(19) United States
(12) Patent Application Publication
(10) Pub. No.: US 2007/0152266 A1
(43) Pub. Date: Jul. 5, 2007

(54) Method and structure for reducing the external resistance of a three-dimensional transistor through use of epitaxial layers

(75) Inventors: Brian S. Doyle, Portland, OR (US); Justin K. Brask, Portland, OR (US); Amlan Majumdar, Portland, OR (US); Suman Datta, Beaverton, OR (US); Jack Kavalieros, Portland, OR (US); Marko Radosavljevic, Beaverton, OR (US); Robert S. Chau, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 11/322,795

(22) Filed: Dec. 29, 2005

(51) Int. Cl. H01L 29/76

(52) U.S. Cl. 257/327

(57) ABSTRACT

The fabrication of a tri-gate transistor formed with a replacement gate process is described. A nitride dummy gate, in one embodiment, is used allowing the growth of epitaxial source and drain regions immediately adjacent to the dummy gate. This reduces the external resistance.

### FIELD OF THE INVENTION

The invention relates to the field of semiconductor processing for transistors having thin channel regions.

### PRIOR ART AND RELATED ART

The trend in the fabrication of complementary metal-oxide-semiconductor (CMOS) transistors is to have small channel regions. Examples of a transistor having a reduced body which includes the channel region along with a tri-gate structure are shown in US 2004/0036127. Other small channel transistors are delta-doped transistors formed in lightly doped or undoped epitaxial layers grown on a heavily doped substrate. See, for instance, “Metal Gate Transistor with Epitaxial Source and Drain Regions,” application Ser. No. 10/955,669, filed Sep. 29,2004, assigned to the assignee of the present application.

One problem with some of these devices is the generally high external resistance that comes about from the thinning of the source and drain regions, sometimes at the edges of the gates. Other devices have similar problems that result in higher external resistance, such as limited available cross-sectional area for source and drain regions. These problems are discussed in conjunction with FIG. 1.

### BRIEF DESCRIPTION OF THE DRAWINGS

FIG. 1 is a cross-sectional, elevation view of a prior art transistor.

FIG. 2A is a perspective view of a semiconductor body, sometimes referred to as a fin, and a dummy gate.

FIG. 2B is a cross-sectional, elevation view of the body and dummy gate of FIG. 2A, taken through section line 2B-2B of FIG. 2A.

FIG. 3 illustrates the structure of FIG. 2B, after an epitaxial growth, and during a first ion implantation process.

FIG. 4 illustrates the structure of FIG. 3, after spacers are fabricated and after a second ion implantation step.

FIG. 5 illustrates the structure of FIG. 4, after forming a dielectric layer and a planarization process.

FIG. 6 illustrates the structure of FIG. 5, after removal of the dummy gate.

FIG. 7 illustrates the structure of FIG. 6, after forming a high-k gate insulating layer and a metal gate layer

### DETAILED DESCRIPTION

A process for fabricating CMOS field-effect transistors and the resultant transistors are described. In the following description, numerous specific details are set forth, such as specific dimensions and chemical regimes, in order to provide a thorough understanding of the present invention. It will be apparent to one skilled in the art that the present invention may be practiced without these specific details. In other instances, well-known processing steps, such as cleaning steps, are not described in detail, in order to not unnecessarily obscure the present invention.

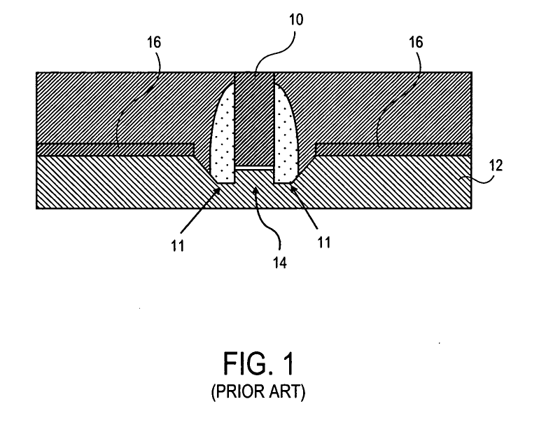

A problem associated with small body transistors is illustrated in FIG. 1. A gate structure 10 is shown traversing a semiconductor body 12 at a channel region 14 of a transistor having source/drain regions 16. The semiconductor body or fin is thinned at the gate edges 11. This thinning is the result of processing used for defining the body, forming spacers, and cleaning of oxides. This processing can reduce the body such that it may no longer have sufficient crystalline seed to support the growth of an epitaxial layer. Often, as much as 20-50% of the body at the edge of the gate can be lost during such processing. In addition to yield loss, this results in higher source/drain resistance and the consequential reduction in transistor performance. The problem of thinning at the gate edges occurs not only in tri-gate structures with silicon-on-insulator (SOI) substrates, but also in some bulk silicon layer and delta-doped transistors.

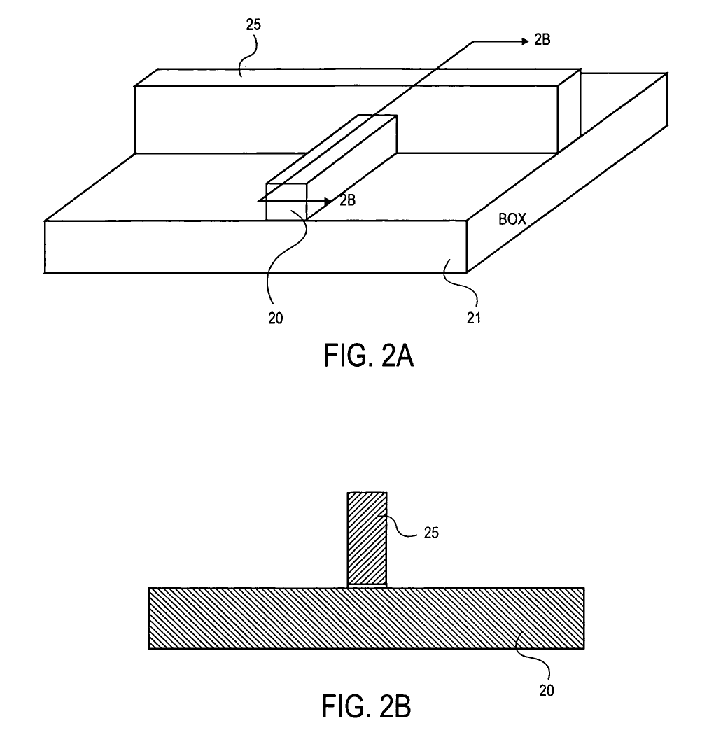

As illustrated in FIG. 2A, a semiconductor body 20 is fabricated on a buried oxide layer (BOX) 21. The body 20, for example, is fabricated from a monocrystalline, silicon layer disposed on the BOX 21. This SOI substrate is well-known in the semiconductor industry. By way of example, the SOI substrate is fabricated by bonding the BOX 21 and a silicon layer onto a substrate (not illustrated), and then planarizing the silicon layer so that it is relatively thin. Other techniques are known for forming an SOI substrate including, for instance, the implantation of oxygen into the silicon substrate to form a buried oxide layer. Other semiconductor materials, other than silicon, may also be used such as gallium arsenide.

A silicon nitride dummy gate structure 25 is formed transverse to the body 20 on, for instance, the BOX 21. The channel region of a transistor is defined at the intersection of the dummy structure 25 and the body 20, as is typically the case in a replacement gate process. The dummy gate structure may be fabricated from other materials, as will be discussed later.

In FIG. 2B, the semiconductor body 20 and silicon nitride dummy gate structure 25 are again shown without the BOX 21. The view of FIG. 2B is generally taken through the section line 2B-2B of FIG. 2A. In FIG. 2B and the remaining figures, the BOX 21 is not shown. The processing described below is not dependent upon the body 20 being fabricated on the BOX 21. In fact, the body 20 may be fabricated from a bulk substrate. For instance, the body 20 may be selectively grown from a monocrystalline silicon substrate or other semiconductor substrate. Alternatively, the body 20 may be formed by selectively etching a monocrystalline semiconductor layer so as to define a plurality of bodies 20.

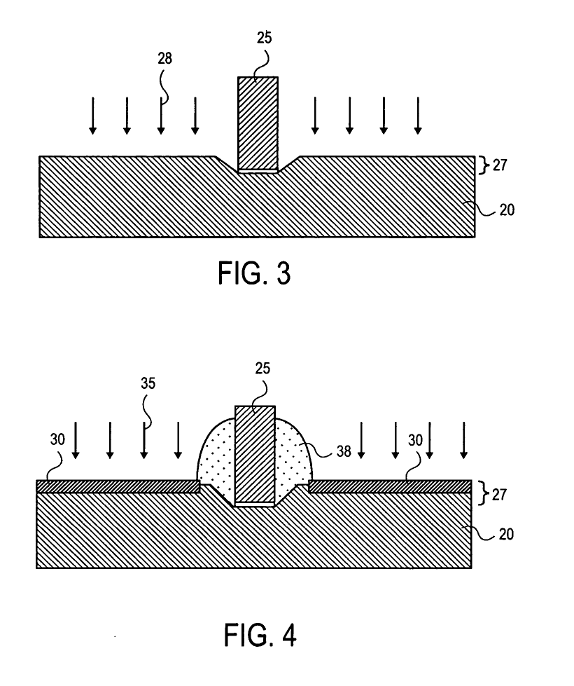

As shown in FIG. 3, an epitaxial layer 27 is grown on the body 20. A silicon or silicon germanium or other semiconductor layer may be grown. Importantly, the layer 27 does not grow on the dummy gate 25. As previously mentioned, the dummy gate 25 is fabricated from silicon nitride, in one embodiment. Thus, an epitaxial growth can occur on the body 20 without it being formed on the dummy gate 25. Note if the dummy gate were a polycrystalline silicon gate, some epitaxial growth would occur on the dummy gate structure. This growth when removed in a subsequent replacement gate process will result in a final gate which is larger than the critical dimension. Therefore, the material for the dummy gate structure is selected such that no epitaxial growth occurs on the structure when the body is being thickened as shown in FIG. 3.

Now, an ion implantation step occurs implanting n type ions for n channel transistors or p-type ions for a p channel transistor. This initial implantation step shown by the lines 28 forms the tip or extension source and drain regions as is typically used. Thus, this implantation step leaves the body 20 relatively lightly doped.

Next, a layer of silicon nitride is conformally deposited over the structure of FIG. 3, and is used to fabricate the spacers 38 shown in FIG. 4. Ordinary, well-known, anisotropic etching may be used to fabricate the spacers. In one embodiment, a carbon-doped nitride, doped with 5-13% carbon concentration is used for the spacers. Other spacers mentioned are discussed later. Prior to the formation of the nitride layer, any oxide present on the body 20 is removed. This cleaning process is one of the processes that typically reduces the thickness of the body at the edges of the gate. After the spacer formation, the main part of the source and drain regions 30 are formed through ion implantation 35. For the n channel device, arsenic or phosphorous is used with an implant dose of up to 1×10¹⁹-1×10²⁰ atoms/cm³. For a p channel device, boron is implanted to the same dose level.

Above a nitride dummy gate and carbon doped nitride spacers are used. This combination of materials allows growth of the epi-layer without growth on the dummy gate and allows the removal of the dummy gate without etching the spacers. Other examples of dummy gate materials include an amorphous material with polar bonding, such as a CVD-based silicon dioxide or a carbon-doped silicon nitride. For the latter material, the spacers can be made from an oxide. In this case, the doping of the source/drain regions help improve the selectivity between the dummy gate and the spacers because the spacers get doped.

Alternatively, after the spacers 38 are formed a second epitaxial layer may be grown on the epitaxial layer 27 to further thicken the body and the source and drain regions, and thereby further reduce the external resistance of the subsequently formed transistor. The main source and drain regions 30 will then be raised (not illustrated) above the edge of the spacers 38.

For a p channel transistor, where the second epitaxial growth is used, the source and drain regions may be formed by selectively depositing epitaxial boron (B) doped silicon or SiGe with germanium concentrations up to 30%, as an example. Under the processing conditions of 100 sccm of dichlorosilane (DCS), 20 slm H₂, 750-800° C., 20 Torr, 150-200 sccm HCl, a diborane (B₂H₆) flow of 150-200 sccm and a GeH₄ flow of 150-200 sccm, a highly doped SiGe film with a deposition rate of 20 nm/min, B concentration of 1E20 cm⁻³ and a germanium concentration of 20% is achieved. A low resistivity of 0.7-0.9 mOhm-cm resulting from the high B concentration in the film provides the benefit of high conductivity in the tip source/drain regions and thereby reduced Rₑₓₜₑᵣₙₐₗ. SiGe in the source/drain regions exerts compressive strain on the channel, which in turn results in enhanced mobility and improved transistor performance.

For an NMOS transistor, the source/drain regions are formed, for instance, using in-situ phosphorous doped silicon deposited selectively under processing conditions of 100 sccm of DCS, 25-50 sccm HCl, 200-300 sccm of 1% PH₃ with a carrier H₂ gas flow of 20 slm at 750° C. and 20 Torr. A phosphorous concentration of 2E20 cm⁻³ with a resistivity of 0.4-0.6 mOhm-cm is achieved in the deposited film.

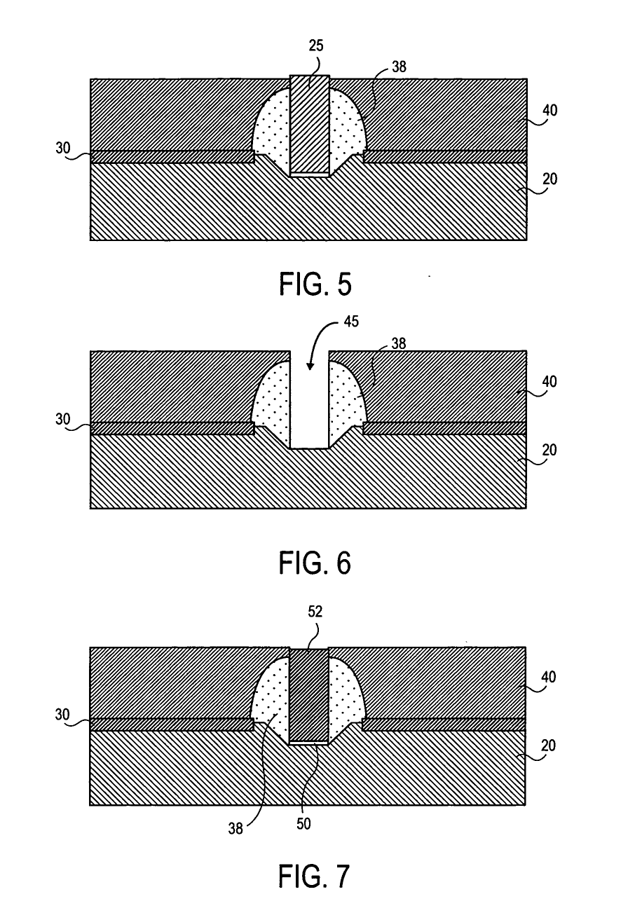

A dielectric layer 40 is now conformally deposited over the structure of FIG. 4, as shown in FIG. 5. This may comprise a silicon dioxide layer which will become an interlayer dielectric (ILD) in an integrated circuit. A low-k dielectric or a sacrificial dielectric layer may be used. In any event, the layer 40 typically has the mechanical strength to withstand a planarization process such as chemical mechanical polishing (CMP).

At this point in the processing, or earlier, annealing occurs to, in part, activate the doping.

After the deposition and planarization of the dielectric layer 40, a wet etch is used to remove the dummy nitride gate 25, leaving the opening 45, as shown in FIG. 6. Any dummy gate oxide that remains is also removed. A wet etchant (such as H₃PO₄) that selectively etches nitride without attaching the body 25 or substantially etching the spacers 38.

Next, a gate dielectric 50 is formed on the exposed surfaces which includes the sides and top of the body 20 lying within the opening 45. The gate dielectric, in one embodiment, has a high dielectric constant (k), such as a metal oxide dielectric, for instance, HfO₂ or ZrO₂ or other high k dielectrics, such as PZT or BST. The gate dielectric may be formed by any well-known technique such as atomic layer deposition (ALD) or chemical vapor deposition (CVD). Alternately, the gate dielectric may be a grown dielectric. For instance, the gate dielectric 50, may be a silicon dioxide film grown with a wet or dry oxidation process to a thickness between 5-50 Å.

Following this, also as seen in FIG. 7, a gate electrode (metal) layer 52 is formed over the gate dielectric layer 50. The gate electrode layer 52 may be formed by blanket deposition of a suitable gate electrode material. In one embodiment, a gate electrode material comprises a metal film such as tungsten, tantalum, titanium and/or nitrides and alloys thereof. For the n channel transistors, a work function in the range of 3.9 to 4.6 eV may be used. For the p channel transistors, a work function of 4.6 to 5.2 eV may be used. Accordingly, for substrates with both n channel and p channel transistors, two separate metal deposition processes may need to be used.

The metal layer 52 is planarized using, for example CMP, and the planarization continues until at least the upper surface of the dielectric layer 40 is exposed, as shown in FIG. 7.

Ordinary processing is now used to complete the transistor of FIG. 7, for instance, contacts are formed to the gate and source and drain regions.

Significantly, in comparing the transistor of FIG. 7 with the prior art transistor of FIG. 1, it should be noted that there is no thinning 11 shown in FIG. 1. Rather as shown in FIG. 7, since epitaxial growth was possible in alignment with the dummy gate, the cross-section of the body is actually larger outside of the channel region than in the channel region. This is in sharp contrast to the prior art drawing of FIG. 1 where there is a substantial thinning of the body beyond the channel region which greatly adds to the external resistance of the transistor.

What is claimed is:

1. A method for forming a field-effect transistor comprising:
forming a dummy gate over a semiconductor body from a first material;
growing an epitaxial semiconductor layer on the body in alignment with the dummy gate such that no growth occurs on the first material;
forming source and drain regions in the body, at least in part, in alignment with the dummy gate; and
replacing the dummy gate with a conductive gate insulated from the body.

2. The method defined by claim 1, wherein the body is a silicon body.

3. The method defined by claim 1, wherein the dummy gate covers two opposite sides and an upper surface of the body.

4. The method defined by claim 1, wherein the forming of the source and drain regions comprises:
doping the body in alignment with the dummy gate;
forming spacers on opposite sides of the dummy gate from a second material selected such that the first material can be etched without substantially etching the second material; and
doping the body in alignment with the spacers.

5. The method defined by claim 1, wherein the replacing of the dummy gate includes:
surrounding the dummy gate with a dielectric material; and
etching the dummy gate without substantially etching the body and the dielectric material, thereby exposing a channel region in the body.

6. The method defined by claim 5, including:
forming a high-k gate dielectric on the channel region of the body; and
forming a metal gate over the high-k gate dielectric.

7. The method defined by claim 6, wherein the metal gate has a work function between the range of 3.9 to 5.2 eV.

8. The method defined by claim 7, wherein the forming of the source and drain regions includes:
doping the body in alignment with the dummy gate;
forming spacers on opposite sides of the dummy gate from a second material selected such that the first material can be etched without substantially etching the second material; and
doping the body in alignment with the spacers.

9. The method defined by claim 4, including forming an additional epitaxial growth on the body following the formation of the spacers.

10. The method defined by claim 9, wherein the body comprises silicon.

11. The method defined by claim 9, wherein the replacing of the dummy gate includes:
surrounding the dummy gate with a dielectric material; and
etching the dummy gate without substantially etching the dielectric material or the body, thereby exposing a channel region in the body.

12. The method defined by claim 11, including
forming a high-k dielectric on the channel region of the body; and
forming a metal gate over the high-k dielectric.

13. The method defined by claim 12, wherein the metal gate has a work function between the range of 3.9 to 5.2 eV.

14. In the formation of a field-effect transistor using a replacement gate process, an improvement comprising:
forming a silicon nitride sacrificial gate over a semiconductor body;
increasing dimensions of the semiconductor body not covered by the sacrificial gate through epitaxial growth; and
surrounding the sacrificial gate with a dielectric material such that the sacrificial gate can be etched without substantially etching the dielectric material or the body.

15. The process defined by claim 14, including forming source and drain regions in the body, at least in part, in alignment with the sacrificial gate.

16. The process defined by claim 15, wherein forming the source and drain region includes:
doping the body in alignment with the sacrificial gate;
forming spacers on opposite sides of the sacrificial gate; and
doping the body in alignment with the spacers.

17. The process defined by claim 16, including:
removing the sacrificial gate without substantially removing the dielectric or the body thereby defining a channel region;
forming a high-k dielectric on the channel region of the body; and
forming a metal gate on the high-k dielectric.

18. A transistor comprising:
a semiconductor body having a channel region and source and drain regions on opposite sides of the channel region, the body having epitaxial regions providing greater cross-sectional area immediately adjacent to the channel region, the greater cross-sectional area of the body including both a tip source and drain region, and a main source and drain region;
a high-k gate dielectric on the channel region of the body; and
a metal gate disposed on the high-k gate dielectric.

19. The transistor defined by claim 18, wherein the metal gate has a work function between 3.9 and 5.2 eV.

20. The transistor defined by claim 18, including spacers disposed on the body over the tip source and drain regions.
